(19) United States
(12) Patent Application Publication
(10) Pub. No.: US 2009/0127594 A1
(43) Pub. Date: May 21, 2009

(54) MOS TRANSISTORS HAVING NiPtSi CONTACT LAYERS AND METHODS FOR FABRICATING THE SAME

(75) Inventors: Valli ARUNACHALAM, Pleasant Valley, NY (US); Paul R. BESSER, Sunnyvale, CA (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/942,094

(22) Filed: Nov. 19, 2007

(51) Int. Cl. H01L 21/441; H01L 21/336; H01L 29/78

(52) U.S. Cl. 257/288; 438/655; 438/301; 257/E21.477; 257/E21.438; 257/E29.255

(57) ABSTRACT

MOS transistors and methods for fabricating MOS transistors are provided. One exemplary method comprises providing a silicon substrate having an impurity-doped region disposed at a surface of the silicon substrate. A first layer is sputter-deposited onto the impurity-doped region using a first sputtering target comprising nickel and a first concentration of platinum. A second layer is sputter-deposited onto the first layer using a second sputtering target comprising nickel and a second concentration of platinum, wherein the second concentration of platinum is less than the first.

### FIELD OF THE INVENTION

The present invention generally relates to semiconductor devices and methods for fabricating semiconductor devices, and more particularly relates to MOS transistors having NiPtSi contact layers and methods for fabricating MOS transistors having NiPtSi contact layers.

### BACKGROUND OF THE INVENTION

Cobalt silicide (CoSi₂) has been used widely for contact layers of 90 nm technology metal-oxide-semiconductor (MOS) devices. However, as device size continues to decrease to 65 nm technologies and beyond, the use of CoSi₂ becomes more difficult. In particular, the constant reduction in gate dimensions leads to drastic increases in contact resistance because of voiding in the CoSi₂ contact. In addition, CoSi₂ is relatively incompatible with embedded silicon germanium integration schemes and tends to consume too much silicon associated with silicon-on-insulator (SOI) substrates. Nickel silicide (NiSi) has become a viable alternative to CoSi₂. NiSi eliminates the contact resistance problem associated with scaling, is compatible with SiGe substrates, and requires less silicon consumption.

However, NiSi is not without its challenges: 1) the nickel-disilicide (NiSi₂) phase has been observed to form at very low temperatures; 2) excessive nickel diffusion has been observed on narrow active areas; and 3) NiSi can be morphologically unstable and can degrade through thermal grooving and agglomeration. The incorporation of platinum (Pt) into NiSi films has been found to delay both the morphological instability of NiSi and the formation of NiSi₂, and meets the demanding integration requirements for implementation into high-performance 65 nm technology. In particular, platinum minimizes the number of NiSi₂ “pipes” and other defects that form in the nickel-silicide layer. NiSi pipes are silicide defects that propagate from the source/drain active areas under the gate spacer into the gate channel, thus leading to transistor failure.

Incorporation of platinum into a nickel silicide layer poses several challenges. While the presence of platinum in a NiPtSi layer delays agglomeration of NiSi and the formation of the higher resistivity NiSi₂ phase, it increases the resistivity of the silicide layer. To keep the resistivity low, NiPtSi layers typically are formed with a platinum concentration of only about 5 at. %. At such low platinum concentrations, the propensity for silicide-induced defect formation increases. Examples of such defects include silicide encroachment under the gate causing shorting in the active areas. Therefore, it is important to deposit a NiPt layer that has an optimum concentration of platinum so that a satisfactory balance between the number of defects and the resistivity of the layer is realized. Further, platinum is expelled from the silicide layer to form nickel disilicide during subsequent rapid thermal annealing (RTA) processes and/or subsequent backend fabrication processes that require high temperatures. Thus, it is important that a sufficient concentration of platinum be incorporated into the silicide layer so that, after subsequent high temperature processes, enough platinum is present in the silicide layer to minimize defects.

Accordingly, it is desirable to provide MOS transistors with silicide contacts that have NiPtSi layers with a platinum concentration that minimizes defects while maintaining low resistivity. In addition, it is desirable to provide MOS transistors that have NiPtSi layers wherein platinum is disposed proximate to a silicon substrate surface for retardation of nickel diffusion. Further, it is desirable to provide methods for fabricating such MOS transistors. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for fabricating silicide contacts of a semiconductor device in accordance with an exemplary embodiment of the invention is provided. The method comprises providing a silicon substrate having an impurity-doped region disposed at a surface of the silicon substrate. A first layer is sputter-deposited onto the impurity-doped region using a first sputtering target comprising nickel and a first concentration of platinum. A second layer is sputter-deposited onto the first layer using a second sputtering target comprising nickel and a second concentration of platinum, wherein the second concentration of platinum is less than the first.

A method for fabricating an MOS transistor in accordance with an exemplary embodiment of the present invention is provided. The method comprises implanting ions of a conductivity-determining impurity type into a silicon substrate to form an impurity-doped region of the silicon substrate. The impurity-doped region is subjected to a first plasma vapor deposition process using a first sputtering target comprising nickel and a first concentration of platinum in the range of at least about 10 at. % platinum. The impurity-doped region is subjected to a second plasma vapor deposition process using a second sputtering target comprising nickel and a second concentration of platinum that is less than the first concentration of platinum. A NiPtSi layer having an effective concentration of platinum in the range of about 5 at. % to about 20 at. % platinum is formed.

A method for fabricating an MOS transistor in accordance with another exemplary embodiment of the present invention is provided. The method comprises forming a gate stack on a silicon substrate and implanting ions of a conductivity-determining impurity type into the silicon substrate using the gate stack as an implantation mask to form impurity-doped regions of the silicon substrate. The impurity-doped regions are subjected to a first plasma vapor deposition process using a first sputtering target comprising nickel and about 10 at. % to about 50 at. % platinum. The impurity-doped regions are subjected to a second plasma vapor deposition process using a second sputtering target comprising nickel and about 0 at. % to about 10 at. % platinum. The silicon substrate is heated using rapid thermal annealing.

An MOS transistor in accordance with an exemplary embodiment of the present invention is provided. The MOS transistor comprises a gate stack disposed on a silicon substrate, the silicon substrate having a surface. An impurity-doped region is disposed at the surface of the silicon substrate and is self-aligned to the gate stack. An NiPtSi layer is disposed on the impurity-doped region. The NiPtSi layer has an effective concentration of platinum in the range of about 5 at. % to about 20 at. % and has a proportion of platinum atoms within a thickness of the NiPtSi layer proximate to the surface of the silicon substrate that is higher than a proportion of platinum atoms of any other portion of the NiPtSi layer having the same thickness.

### BRIEF DESCRIPTION OF THE DRAWINGS

The present invention will hereinafter be described in conjunction with the following drawing figures, wherein like numerals denote like elements, and wherein:

FIGS. 1-11 illustrate a method for fabricating an MOS transistor in accordance with an exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

The various embodiments of the present invention result in the fabrication of an MOS transistor with a NiPtSi layer that has an “effective” or average platinum concentration in the range of about 5 at. % to about 20 at. %, preferably less than about 10 at. %. An effective platinum concentration in this range is sufficiently low to provide a desirably low resistivity of the silicide layer. However, the NiPtSi layer has a high proportion of platinum atoms proximate to the surface of the silicon substrate, that is, at the silicide-silicon interface compared to the rest of the NiPtSi layer. This is achieved using a two step plasma vapor deposition (PVD) process. By sputter-depositing a higher concentration of platinum on the surface of the silicon substrate in a first sputtering process and by following with a second sputtering process using a lower platinum concentration, a NiPtSi layer sufficiently thick for electric conductivity is fabricated with a higher proportion of the platinum proximate to the surface of the silicon substrate compared to the rest of the silicide layer. A high concentration of platinum at the silicide-silicon interface is more effective at minimizing the number of defects caused by nickel diffusion and by NiSi₂ formation than if the platinum was evenly distributed throughout the NiPtSi layer. Thus, a NiPtSi layer with low resistivity and low defect count and high device yield can be achieved.

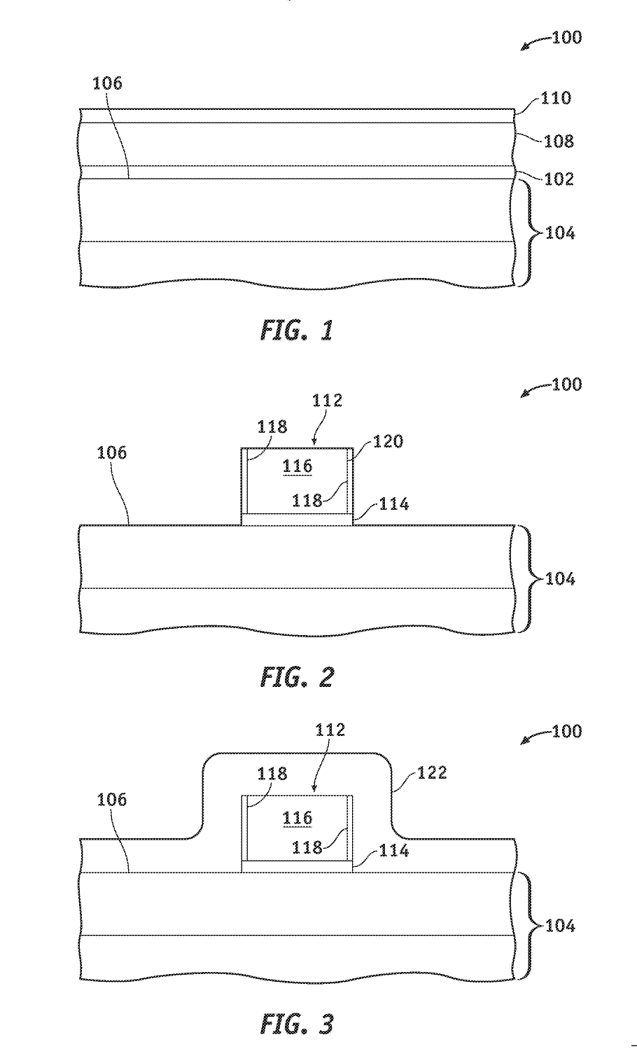

FIGS. 1-11 illustrate, in cross section, a method for forming an MOS transistor 100 in accordance with exemplary embodiments of the invention. Although the term “MOS transistor” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a silicon substrate. The MOS transistor 100 can be a P-channel MOS (PMOS) transistor or an N-channel MOS (NMOS) transistor. While the fabrication of only one MOS transistor is illustrated, it will be appreciated that the method of FIGS. 1-11 can be used to fabricate any number of NMOS transistors and/or PMOS transistors. Various steps in the manufacture of MOS components are well known and so, in the interest of brevity, many conventional steps will only be mentioned briefly herein or will be omitted entirely without providing the well known process details.

Referring to FIG. 1, the method begins by forming a gate insulator material 102 overlying a silicon substrate 104. The term “silicon substrate” is used herein to encompass the relatively pure silicon materials typically used in the semiconductor industry as well as silicon admixed with other elements such as germanium, carbon, and the like. The silicon substrate may be a bulk silicon wafer, or may be a thin layer of silicon on an insulating layer (commonly know as silicon-on-insulator or SOI) that, in turn, is supported by a carrier wafer. At least a surface 106 of the silicon substrate is impurity doped, for example by forming N-type well regions and P-type well regions for the fabrication of P-channel (PMOS) transistors and N-channel (NMOS) transistors, respectively.

In the conventional processing, the layer 102 of gate insulating material can be a layer of thermally grown silicon dioxide or, alternatively (as illustrated), a deposited insulator such as a silicon oxide, silicon nitride, or the like. Deposited insulators can be deposited, for example, by chemical vapor deposition (CVD), low pressure chemical vapor deposition (LPCVD), or plasma enhanced chemical vapor deposition (PECVD). Gate insulator layer 102 preferably has a thickness of about 1-10 nm, although the actual thickness can be determined based on the application of the transistor in the circuit being implemented.

A layer of gate electrode material 108 is formed overlying the gate insulating material 102. In accordance with one embodiment of the invention, the gate electrode material is polycrystalline silicon. The layer of polycrystalline silicon is preferably deposited as undoped polycrystalline silicon and is subsequently impurity doped by ion implantation. The polycrystalline silicon can be deposited by LPCVD by the hydrogen reduction of silane. A layer of hard mask material 110, such as silicon nitride or silicon oxynitride, can be deposited onto the surface of the polycrystalline silicon. The hard mask material can be deposited to a thickness of about 50 nm, also by LPCVD. Alternatively, it will be appreciated that a photoresist may be deposited onto the surface of the polycrystalline silicon instead of the hard mask material.

Referring to FIG. 2, the hard mask layer 110 is photolithographically patterned and the underlying gate electrode material layer 108 and the gate insulating material layer 102 are etched to form a gate stack 112 having a gate insulator 114 and a gate electrode 116. The polycrystalline silicon can be etched in the desired pattern by, for example, reactive ion etching (RIE) using a Cl⁻ or HBr/O₂ chemistry and the hard mask and gate insulating material can be etched, for example, by RIE in a CHF₃, CF₄, or SF₆ chemistry. Reoxidation sidewall spacers 118 are formed about sidewalls 120 of gate stack 112 by subjecting the gate electrode 116 to high temperature in an oxidizing ambient. The reoxidation sidewall spacers 118 have a thickness of, for example, about 3 to 4 nm. The hard mask then is removed.

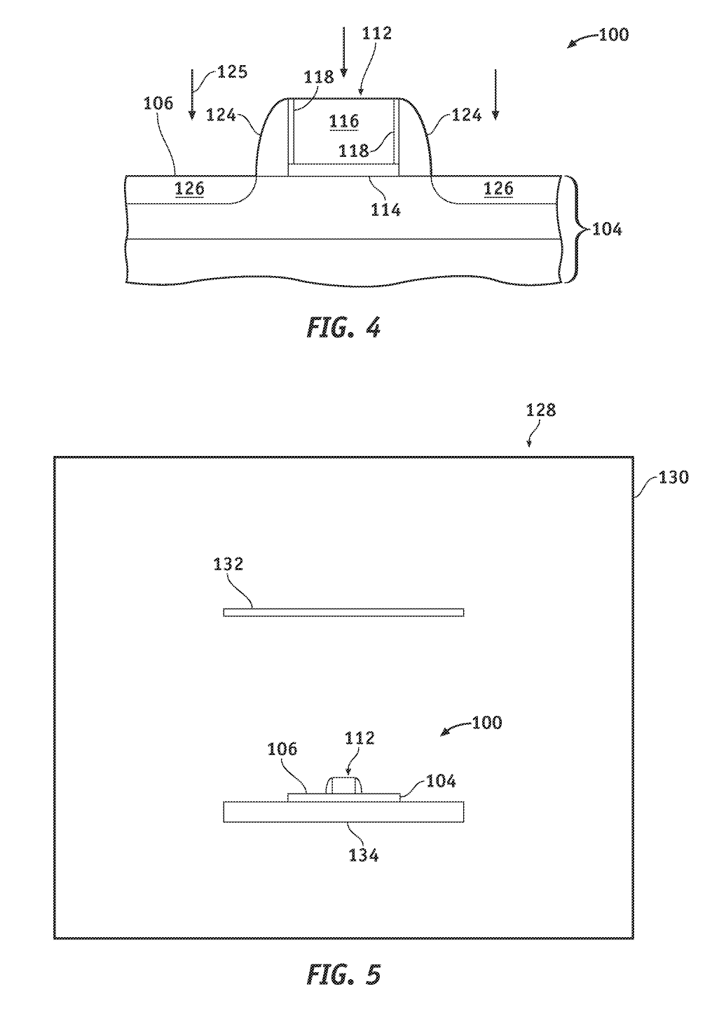

After the formation of the reoxidation sidewall spacers 118, a blanket layer 122 of dielectric material is deposited overlying MOS structure 100, as illustrated in FIG. 3. The dielectric material layer may comprise, for example, silicon dioxide. The dielectric material layer 122 is anisotropically etched, as described above, to form second spacers 124, often referred to as offset spacers, adjacent to the reoxidation sidewall spacers 118, as illustrated in FIG. 4. The offset spacers have a thickness of, for example, about 10 to about 20 nm. While FIG. 4 illustrates MOS transistor 100 with two sidewall spacers, it will be understood that the invention is not so limited and MOS transistor 100 may have just one sidewall spacer or more than two sidewall spacers as is suitable for a desired functionality of MOS transistor 100.

The reoxidation spacers 118 and the offset spacers 124 are used along with the gate stack 112 as an ion implantation mask for formation of source and drain regions 126. By using the gate stack 112 and the spacers 118 and 124 as an ion implantation mask, the source and drain regions are self aligned with the gate stack and the spacers. The source and drain regions are formed by appropriately impurity doping silicon substrate 104 in known manner, for example, by ion implantation of dopant ions, illustrated by arrows 125, and subsequent thermal annealing. For an N-channel MOS transistor the source and drain regions 126 are preferably formed by implanting arsenic ions, although phosphorus ions could also be used. For a P-channel MOS transistor, the source and drain regions are preferably formed by implanting boron ions. MOS transistor 100 then may be cleaned to remove any oxide that has formed on the silicon substrate surface 106. The MOS transistor 100 may be cleaned, for example, by a wet etch chemistry such as buffered hydrofluoric acid (BHF) or dilute hydrofluoric acid.

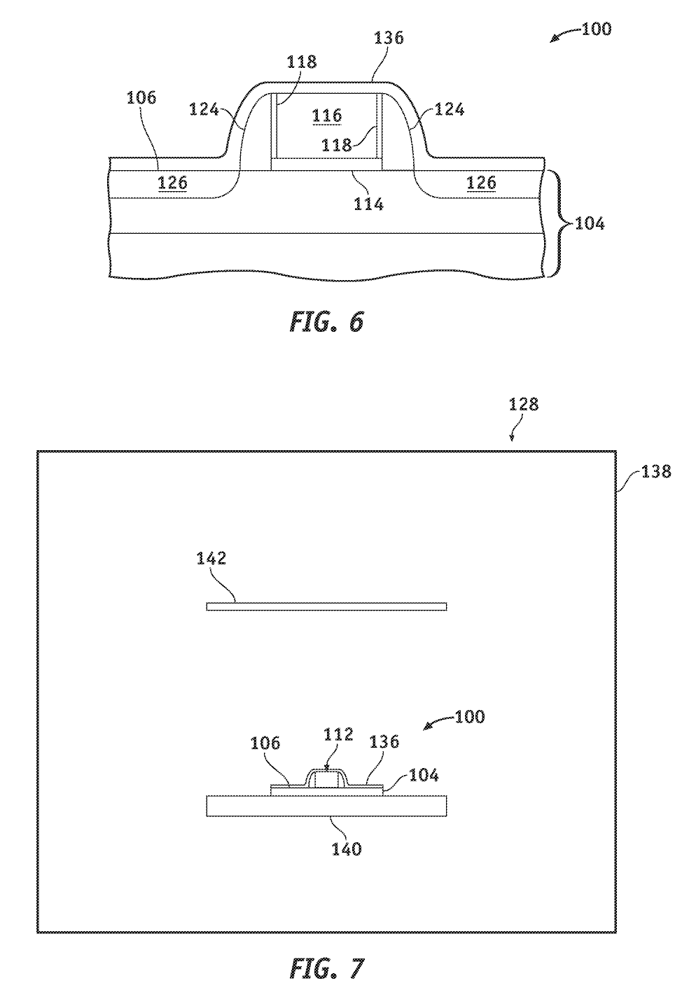

The method continues with the disposition of the MOS transistor 100 onto a substrate support 134 of a first chamber 130 of a PVD apparatus 128, as illustrated in FIG. 5. It will be appreciated that prior to being disposed in the first chamber, the MOS transistor may be placed inside a remote-plasma chamber of PVD apparatus 128 and surface 106 of the silicon substrate 104 of MOS transistor 100 subsequently may be cleaned by plasma etch to remove any oxide that has formed on the silicon substrate since the wet clean process described above. The plasma may be formed using, for example, an argon, NF₃, or NH₃ source. First chamber 130 of PVD apparatus 128 includes a first sputtering target 132 comprising nickel and a first concentration of platinum. In one embodiment of the present invention, the first concentration of platinum is in the range of about 10 at. % to about 50 at. %. The concentration of the platinum used in the first chamber depends on factors such as the node technology used to fabricate MOS transistor 100, the integration scheme used, thickness of the NiPtSi layer to be formed on silicon substrate 104, and the resistivity of the NiPtSi layer that can be tolerated during operation of MOS transistor 100. The temperature of the silicon substrate 104 of MOS transistor is maintained by the substrate support 134 within the range of about −40° C. to about 150° C. The first chamber can be evacuated to a base ultrahigh vacuum pressure of, for example, 10⁻⁷ atmospheres (atm) and sputtering can be conducted at a sputter pressure in the range of about 0.5 to about 10 millitorr (mTorr). Referring to FIG. 6, a blanket layer 136 of a nickel platinum (Ni₁₋ₓPtₓ, wherein 0.1≦x≦0.5) is deposited overlying MOS transistor 100. In one exemplary embodiment, the Ni₁₋ₓPtₓ layer is deposited on surface 106 of silicon substrate 104 with a sufficient thickness so that it is continuous. Those skilled in the art will appreciate that commercially-available, ultra-high vacuum tools containing multiple process chambers can be used for the cleaning and deposition processes described here.

Referring to FIG. 7, MOS transistor 100 then is disposed onto a substrate support 140 of a second chamber 138 of PVD apparatus 128 without a break in the vacuum pressure. Second chamber 138 includes a second sputtering target 142 comprising nickel and a second concentration of platinum that is less than the first concentration of platinum of first sputtering target 132. In an exemplary embodiment, the second concentration is in the range of about 0 to no more than about 10 at. % platinum. The concentration of the platinum used in the second chamber also depends on factors such as the node technology used to fabricate MOS transistor 100, the integration scheme used, thickness of the NiPtSi layer to be formed on silicon substrate 104, and the resistivity of the NiPtSi layer that can be tolerated during operation of MOS transistor 100. Sputtering within second chamber 138 can be performed using conditions within the same ranges as set forth above with respect to the sputtering process performed in first chamber 130. Referring to FIG. 8, the sputtering in second chamber 138 continues with the deposition of Ni_{1-y}Pt_{y}, where 0≦y≦0.1, onto the N₁₋ₓPtₓ layer until the entire nickel-platinum layer 160 (Ni₁₋ₓPtₓ and Ni_{1-y}Pt_{y}) is continuous but has a thickness, indicated by double-headed arrow 144, that is no more than about 15 nm and preferably is in the range of about 7 to about 10 nm. In another exemplary embodiment of the invention, thickness 144 is about at least 2 monolayers and preferably is about 4 monolayers. In an optional exemplary embodiment, after sputtering in the second chamber 138, a cap 146 can be formed on the nickel platinum layer 160. Cap 146 protects the nickel-platinum layer 160 from oxidation after MOS transistor 100 is removed from PVD apparatus 128 and during subsequent annealing. The cap can comprise, for example, titanium, or titanium nitride. While the above-described PVD process utilizes two sputtering processes, each performed in a different chamber, it will be appreciated that both sputtering processes can be performed in one chamber that utilizes the first and second sputtering targets.

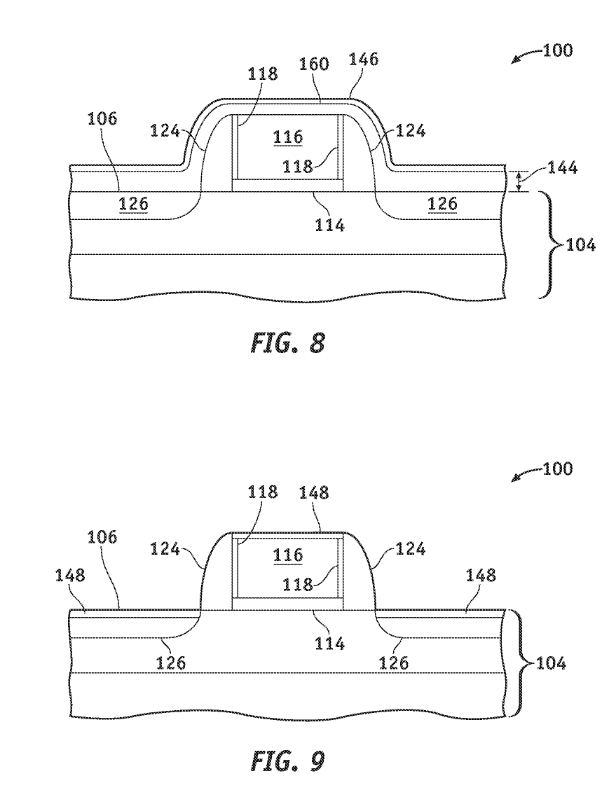

Referring to FIG. 9, MOS transistor 100 is subjected to a rapid thermal anneal (RTA), preferably to form a NiPtSi layer 148 at the surface 106 of silicon substrate 104 and on the polysilicon gate electrode 116. The anneal is performed at temperatures in the range of about 320° C. to about 500° C., preferably in the range of about 360° C. to about 420° C. Any nickel platinum that is not in contact with exposed silicon, for example the nickel platinum that is deposited on offset spacers 124, does not react during the RTA to form a silicide and may subsequently be removed by a wet etching solution such as a HNO₃/HCl solution, commonly known as Aqua Regia. The cap 146, if present, also can be removed at this time using a H₂O₂/H₂SO₄ solution. The cap can be removed during removal of the unreacted nickel platinum or can be removed in a previous and/or separate wet etching step. The chemistry of a wet etch used to remove the cap depends on the composition of the cap.

In one exemplary embodiment of the invention, if the RTA temperature was not sufficiently high to produce stoichiometric NiPtSi but, rather, a nickel-rich platinum silicide layer was formed, and no subsequent backend fabrication process will be performed at temperatures sufficiently high to convert the nickel-rich platinum silicide to NiPtSi, a second anneal can be performed. In one exemplary embodiment, the second anneal is performed at temperatures in the range of about 400° C. to about 500° C. after the removal of the unreacted nickel platinum and the cap.

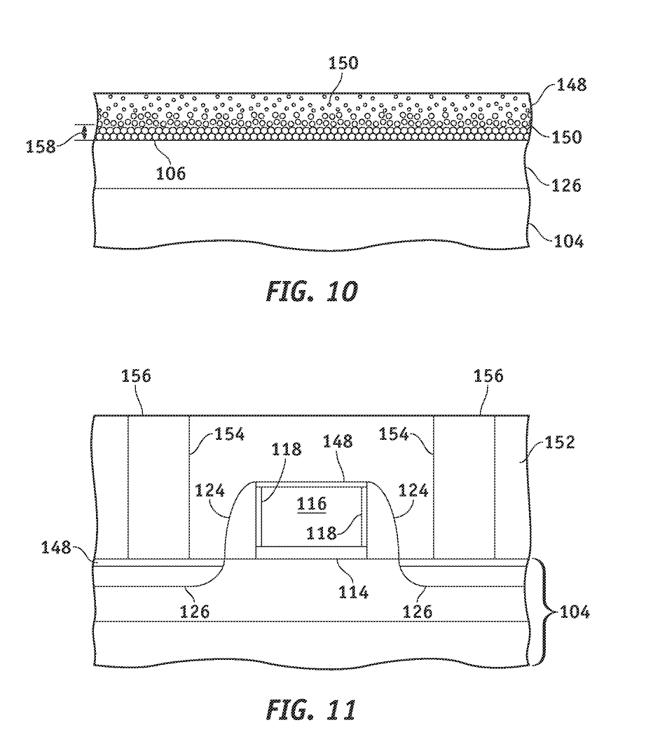

FIG. 10 is a close-up cross-sectional view of NiPtSi layer 148 formed on surface 106 of silicon substrate 104. The NiPtSi layer 148 has an “effective” or average platinum concentration in the range of about 5 at. % to about 20 at. %, preferably less than about 10 at. %. For example, by using a first sputtering target of nickel and about 10 at. % platinum to grow a 5 nm Ni₁₋ₓPtₓ layer and using a second sputtering target of nickel and 0% platinum to grow a 5 nm Ni_{1-y}Pt_{y} layer, a resulting 10 nm NiPtSi layer 148 can be fabricated having an effective platinum concentration of about 5 at %. In another example, a first sputtering target of nickel and about 30 at. % platinum can be used to grow a 3.3 nm Ni₁₋ₓPtₓ layer and a second sputtering target of nickel and 0% platinum can be used to grow an additional 6.7 nm of Ni. After annealing, this results in a 10 nm NiPtSi layer having an effective platinum concentration of about 10 at %. In a further example, a first sputtering target of nickel and about 20 at. % platinum can be used to grow a 5 nm Ni₁₋ₓPtₓ layer and a second sputtering target of nickel and 7.5 at. % platinum can be used to grow an additional 5 nm of Ni. After annealing, this results in a 10 nm NiPtSi layer having an effective platinum concentration of about 10 at %. An effective platinum concentration in this range is sufficiently low so that resistivity of the silicide layer is not undesirably high. However, as illustrated in FIG. 10, the NiPtSi layer 148 has a higher proportion of platinum atoms 150 within a thickness, indicated by double-headed arrow 158, at the surface 106 of the silicon substrate 104 than any portion of the rest of the NiPtSi layer 148 having the same thickness. For example, the NiPtSi layer 148 may have a higher concentration of platinum atoms within the 2 nm closest to the silicide-silicon interface than any other 2 nm-thick portion of the silicide layer. By sputter-depositing a higher concentration of platinum on the surface 106 of silicon substrate 104 in a first sputtering process and by following with a second sputtering process using a lower platinum concentration, a NiPtSi layer sufficiently thick for electric conductivity is fabricated with a higher proportion of the platinum atoms at the surface 106 of the silicon substrate 104 than in the rest of the layer. A high concentration of platinum proximate to surface 106 is more effective at retarding nickel diffusion into the active device areas and minimizing silicide-induced defects than if the platinum was evenly distributed throughout the NiPtSi layer.

Referring to FIG. 11, after removal of any unreacted nickel, and after an optional second anneal, a layer of dielectric material 152 is deposited overlying MOS transistor 100. The method continues, in accordance with an exemplary embodiment of the invention, with the patterning and etching of the dielectric material layer 152 to form a contact opening 154 extending through dielectric material layer 152 and exposing at least a portion of the NiPtSi layer 148 on surface 106 of silicon substrate 104. The dielectric material layer may be planarized by a CMP process before patterning. A conductive contact 156 is formed in contact opening 154 so that the source and drain regions can be appropriately connected electrically to other devices in the integrated circuit to implement the desired circuit function. In an exemplary embodiment of the present invention, conductive contact 156 is formed by the deposition of a thin first barrier layer, such as, for example, titanium (Ti) (not shown), and a thin second barrier layer (not shown), such as, for example, titanium nitride (TiN), within contact opening 154, followed by the deposition of a conductive plug (not shown), such as, for example, W. The barrier layers are used to prevent diffusion of tungsten hexafluoride WF₆, used during formation of the conductive plug, into the dielectric material layer 152 and to enhance adhesion of the conductive plug to the walls of the contact opening. It will be appreciated that other layers may be utilized to form conductive contact 156. For example, the barrier layer can be formed of materials such as tantalum, tantalum nitride, and tungsten nitride and the contact opening can be filled with copper.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

What is claimed is:

1. A method for fabricating silicide contacts of a semiconductor device, the method comprising the steps of:
providing a silicon substrate having an impurity-doped region disposed at a surface of the silicon substrate;
sputter-depositing a first layer onto the impurity-doped region using a first sputtering target comprising nickel and a first concentration of platinum; and
sputter-depositing a second layer onto the first layer using a second sputtering target comprising nickel and a second concentration of platinum, wherein the second concentration of platinum is less than the first.

2. The method of claim 1, wherein the step of sputter-depositing a first layer comprises sputter-depositing the first layer using a first sputtering target comprising nickel and a concentration of platinum in the range of about 10 at. % to about 50 at. %.

3. The method of claim 1, wherein the step of sputter-depositing a second layer comprises sputter-depositing the second layer using a second sputtering target comprising nickel and a concentration of platinum in the range of about 0 to about 10 at. %.

4. The method of claim 1, wherein the steps of sputter-depositing are performed in different chambers of a plasma vapor deposition apparatus.

5. The method of claim 1, wherein the steps of sputter-depositing result in a nickel-platinum layer disposed on the impurity-doped region, wherein the nickel-platinum layer has a thickness in the range of about no greater than 15 nm.

6. The method of claim 1, further comprising, after the steps of sputter-depositing, the steps of subjecting the silicon substrate to a rapid thermal anneal and forming a NiPtSi layer disposed on the impurity-doped region.

7. The method of claim 6, wherein the step of forming a NiPtSi layer comprises the step of forming a NiPtSi layer having a proportion of platinum atoms within a thickness of the NiPtSi layer proximate to the surface of the silicon substrate that is higher than a proportion of platinum atoms of any other portion of the NiPtSi layer having the same thickness.

8. The method of claim 1, wherein, during the steps of sputter-depositing, the silicon substrate is maintained at a temperature in the range of about −40° C. to about 150° C.

9. The method of claim 1, further comprising the step of forming a cap on the second layer.

10. The method of claim 1, further comprising, after the steps of sputter-depositing, the steps of subjecting the silicon substrate to a first rapid thermal anneal and subjecting the silicon substrate to a second subsequent rapid thermal anneal.

11. A method for fabricating an MOS transistor, the method comprising the steps of:
implanting ions of a conductivity-determining impurity type into a silicon substrate to form an impurity-doped region of the silicon substrate;
subjecting the impurity-doped region to a first plasma vapor deposition process using a first sputtering target comprising nickel and a first concentration of platinum in the range of at least about 10 at. % platinum; and
subjecting the impurity-doped region to a second plasma vapor deposition process using a second sputtering target comprising nickel and a second concentration of platinum that is less than the first concentration of platinum and forming a NiPtSi layer having an effective concentration of platinum in the range of about 5 at. % to about 20 at. % platinum.

12. The method of claim 11, wherein the step of subjecting the impurity-doped region to a second plasma vapor deposition process comprises the step of subjecting the impurity-doped region to the second plasma vapor deposition process using a second sputtering target comprising nickel and a concentration of platinum in the range of about 0 to about 10 at. %.

13. The method of claim 11, wherein the step of forming a NiPtSi layer comprises the step of forming a NiPtSi layer having a proportion of platinum atoms within a thickness of the NiPtSi layer proximate to a surface of the silicon substrate that is higher than a proportion of platinum atoms of any other portion of the NiPtSi layer having the same thickness.

14. The method of claim 11, wherein the step of forming a NiPtSi layer comprises the step of heating the silicon substrate during a first rapid thermal anneal process.

15. The method of claim 14, wherein the step of forming a NiPtSi layer further comprises the step of heating the silicon substrate during a second rapid thermal anneal process.

16. The method of claim 14, wherein, during the step of heating, the silicon substrate is heated to a temperature in the range of about 320° C. to about 500° C.

17. The method of claim 11, wherein the step of subjecting the impurity-doped region to a second plasma vapor deposition process results in formation of a nickel-platinum layer on the impurity-doped region, the method further comprising the step of forming a cap on the nickel-platinum layer.

18. The method of claim 11, wherein, during the steps of subjecting, the silicon substrate is maintained at a temperature in the range of about −40° C. to about 150° C.

19. A method for fabricating an MOS transistor, the method comprising the steps of:
forming a gate stack on a silicon substrate;
implanting ions of a conductivity-determining impurity type into the silicon substrate using the gate stack as an implantation mask to form impurity-doped regions of the silicon substrate;
subjecting the impurity-doped regions to a first plasma vapor deposition process using a first sputtering target comprising nickel and about 10 at. % to about 50 at. % platinum;
subjecting the impurity-doped regions to a second plasma vapor deposition process using a second sputtering target comprising nickel and about 0 at. % to about 10 at. % platinum; and
heating the silicon substrate using rapid thermal annealing.

20. The method of claim 19, further comprising the step of forming a NiPtSi layer having a proportion of platinum atoms within a thickness of the NiPtSi layer proximate to a surface of the silicon substrate that is higher than a proportion of platinum atoms of any other portion of the NiPtSi layer having the same thickness.

21. The method of claim 20, wherein the step of forming and the step of heating are performed substantially simultaneously.

22. The method of claim 19, further comprising the step of forming a NiPtSi layer having an effective concentration of platinum in the range of about 5 at. % to about 20 at. %.

23. The method of claim 22, wherein the step of forming and the step of heating are performed substantially simultaneously.

24. An MOS transistor comprising:
a gate stack disposed on a silicon substrate, the silicon substrate having a surface;
an impurity-doped region disposed at the surface of the silicon substrate and self-aligned to the gate stack; and
a NiPtSi layer disposed on the impurity-doped region, wherein the NiPtSi layer has an effective concentration of platinum in the range of about 5 at. % to about 20 at. % and has a proportion of platinum atoms within a thickness of the NiPtSi layer proximate to the surface of the silicon substrate that is higher than a proportion of platinum atoms of any other portion of the NiPtSi layer having the same thickness.
